(19) United States
(12) Patent Application Publication
(10) Pub. No.: US 2020/0211934 A1
(43) Pub. Date: Jul. 2, 2020

(54) LEADFRAME FOR MULTICHIP DEVICES WITH THINNED DIE PAD PORTIONS

(71) Applicant: Texas Instruments Incorporated, Dallas, TX (US)

(72) Inventor: CHANG-YEN KO, TAIPEI CITY (TW)

(21) Appl. No.: 16/237,320

(22) Filed: Dec. 31, 2018

(51) Int. Cl. H01L 23/495; H01L 23/31; H01L 21/48; H01L 21/56; H01L 23/00; H01L 25/10

(52) U.S. Cl. CPC H01L 23/49541; H01L 23/3107; H01L 23/4951; H01L 21/4828; H01L 21/565; H01L 2924/14; H01L 25/105; H01L 2224/48091; H01L 2224/48247; H01L 2224/48257; H01L 2224/49171; H01L 24/49

(57) ABSTRACT

A leadframe for a multichip semiconductor package includes a first die pad and at least a second die pad both vertically offset at least 0.2 mm relative to leads or lead terminals that are positioned on at least 2 sides beyond the first die pad and the second die pad. At least one of the first and second die pads has a reduced thickness portion and a full thickness portion, and wherein the full thickness portion has a same thickness as a thickness of at least an outside portion the leads or the lead terminals.

### FIELD

This Disclosure relates to semiconductor packaging, more particularly to vertically offset (e.g., downset) lead frames for multichip semiconductor packages.

### BACKGROUND

Plastic semiconductor packages include leadframes. A conventional plastic package includes an integrated circuit (IC) die attached to a leadframe, encapsulated in a plastic body. The leadframe supports the die during a molding process, and provides the internal traces and terminal leads of the completed IC package. Leadframes are provided in strips (or panels) adapted to simultaneously form multiple packages, which are subsequently singulated into individual packages.

One type of leadframe includes a mounting paddle (or die pad) for the IC die, and patterns of lead fingers spaced around the peripheries of the mounting paddle. Prior to the molding process, the back side of the die can be attached to the die pad using an adhesive such as epoxy. In addition, metal wires can be wire bonded from bond pads on the die to the lead fingers. Using a transfer molding process, a plastic material, such as an epoxy resin, is molded to either side of the die and leadframe, and over the wire bonded wires. The leadframe is then singulated into multiple packages, and the lead fingers are trimmed and shaped to form the terminal leads of the packages.

One approach to plastic IC packaging involves providing the die pad recessed a depth measured from a plane coincident to a major plane of the leadframe that includes the lead fingers to enable locating the IC die at a level below the major plane in what is termed a downset. The downset improves the wire bonding process by reducing drag forces on the bondwires during wire bonding, and allows the bondwires to be more easily encapsulated by the plastic (mold compound) body.

Some packaged IC devices are multichip module (MCM) devices. One wirebond package arrangement has a plurality of die pads lateral to one another each with an IC die on a die pad.

One particular type of IC device is an isolation device which prevents the propagation of DC and unwanted AC currents between its input and output, while allowing the transmission of the desired AC signal. The isolation device accomplishes this function using an isolation barrier that has a high breakdown voltage and low leakage. A high resistive path exists across the isolation barrier, but the isolation device can still transfer information in the desired AC signal across the isolation barrier by capacitive, inductive, or by optical coupling.

One common reinforced-isolation device arrangement is in the form of a packaged MCM, where each IC die in the package includes at least one embedded high voltage (HV) isolation capacitor (ISO cap), such as using two thick SiO₂ capacitors connected in series by a bondwire between the input and the output that together constitute a double isolation barrier. During MCM isolation device operation there is generally a HV (e.g., 1,000 V root mean square (rms)) applied across the device which generally results in the respective die pads having a large potential difference.

### SUMMARY

This Summary is provided to introduce a brief selection of disclosed concepts in a simplified form that are further described below in the Detailed Description including the drawings provided. This Summary is not intended to limit the claimed subject matter's scope.

Disclosed aspects recognize during packaged MCM isolation (ISO) device operation and testing there can be a high electric field (E field) in the air above and below the bottom side of the mold compound, where the E field intensity below the mold compound can increase relative to the E-field compared to a zero downset die pad. As used herein, a zero downset die pad refers to <0.2 mm of downset. This Disclosure includes a partially etched die pad for at least one of the die pads sometimes referred to herein as a sink pad for packaged MCM ISO devices. Partially etched die pads provide the advantage of gaining more space for thicker components (e.g., inductors) which may increase device efficiency, or a thicker mold compound for reducing the E field in the air above or below the mold compound during testing or operation of the packaged ISO device which can eliminate or at least reduce arcing in the air between leads that arc between a lead connected to high voltage and a lead connected to a ground.

Disclosed aspects include a leadframe for a multichip semiconductor package includes a first die pad and at least a second die pad both vertically offset at least 0.2 mm relative to leads or lead terminals that are positioned on at least 2 sides beyond the first die pad and the second die pad. At least one of the first and second die pads has a reduced thickness portion and a full thickness portion, and wherein the full thickness portion has the same thickness as a thickness of at least an outside portion the leads or the lead terminals.

### BRIEF DESCRIPTION OF THE DRAWINGS

Reference will now be made to the accompanying drawings, which are not necessarily drawn to scale, wherein:

FIG. 1A is a side cross sectional depiction of a packaged MCM device having a conventional downset first and second die pad of a MCM leadframe within a mold compound, and FIG. 1B depicts a side cross sectional depiction of a packaged MCM device having a disclosed downset first and second die pad of a MCM leadframe having a reduced thickness (thinned) die pad portion within a mold compound.

FIG. 1C is a side cross sectional depiction of a packaged MCM device having a conventional vertically shifted up first and second die pad of a MCM leadframe within a mold compound, and FIG. 1D depicts a side cross section depiction of a packaged MCM device having a disclosed vertically shifted up first and second die pad of a MCM leadframe having a reduced thickness (thinned) die pad portion within a mold compound.

FIG. 2A shows a MCM leadframe having first and second die pads having reduced thickness (thinned) die pad portions and full thickness die pad portions, according to an example aspect.

FIG. 2B shows another MCM leadframe having first and second die pads having reduced thickness (thinned) die pad portions and full thickness die pad portions, according to an example aspect.

FIG. 2C shows a MCM leadframe having vertically shifted die pads with a thinned inner lead region and full thickness inner and outer lead portions, with the outer leads portions shown bent down, according to an example aspect.

FIG. 2D shows a MCM leadframe with vertically shifted die pads with a thinned inner lead region and full thickness inner and outer lead portions, with the outer lead portions shown bent up, according to an example aspect.

FIG. 3 is a cross sectional view of an example packaged MCM ISO device having reinforced ISO capacitors wire bonded that has a disclosed MCM leadframe having first and second die pads having reduced thickness (thinned) die pad portions and full thickness die pad portions, according to an example aspect.

FIG. 4 shows an example packaged MCM ISO device that has disclosed die pads with reduced thickness portions, according to an example aspect.

### DETAILED DESCRIPTION

Example aspects are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this Disclosure.

A conventional downset die pad that is typically used to improve the mold flow or increase the height for wire bonding is recognized to result in less mold compound thickness below the die pad as compared to the mold compound thickness above the die pad. This downset arrangement results in the internal E field (the E field lines between the respective die pads) adding more E field to the E field in the air gap between the leads (or land pads that the leads are on) under the mold compound that are biased to different potentials during testing and field use. Typically all leads on one side of the ISO device are biased relative to all the leads on the other side of the ISO device. Field lines extending out of the package from the internal E field adds E field to the external E field thus strengthening the total net E field intensity in the air gap between the leads across the package as well as under the mold compound. If the total E field is high enough to cause air ionization during device testing, the result is ISO test failures that can result in scrapping of packaged ISO devices.

Disclosed packaged ISO devices reduce the E field when biased during testing or while in field use by increasing the mold compound thickness between the location of the minimum internal dielectric spacing (being the gap between the respective die pads) and thus for a downset arrangement particularly in the air region under the mold compound between the external leads which are generally soldered to printed circuit board (PCB) land pads. This mold thickness increase is realized by thinning a portion of the die pads in the package.

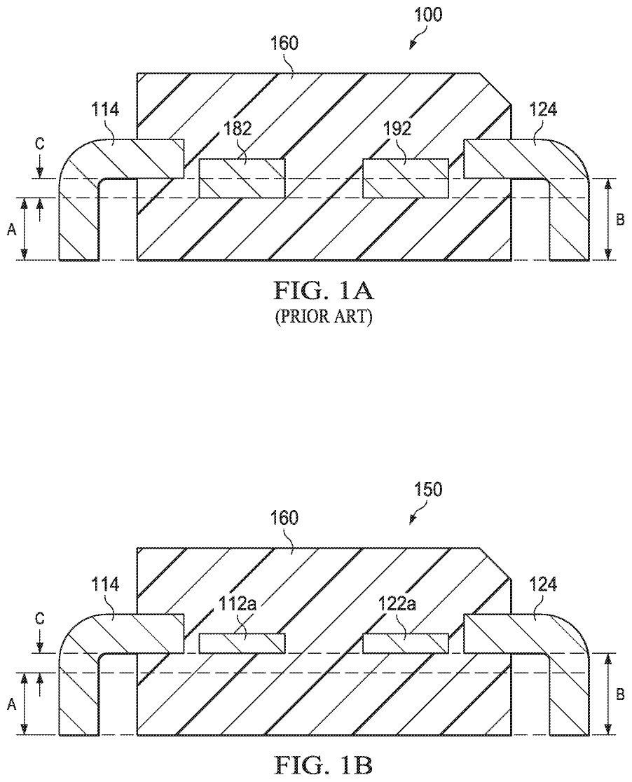

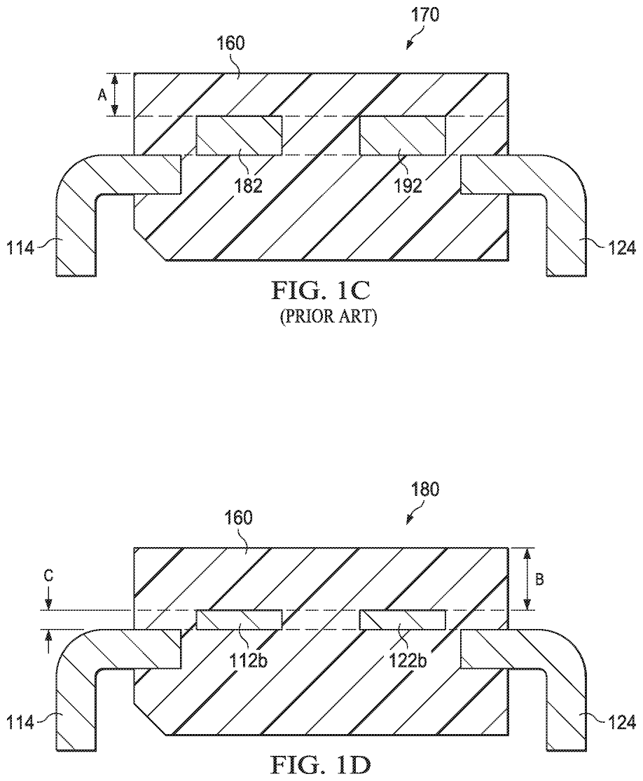

FIG. 1A is a side cross sectional depiction of a packaged MCM device 100 having a conventional downset first die pad 182 and downset second die pad 192 of a MCM leadframe within a mold compound 160. The first die pad 182 and second die pad 192 can be seen to be full thickness die pads that have the same metal thickness as the leads 114 and 124. The distance from the bottom of the die pads 182, 192 to the bottom edge of the mold compound 160 is shown as ‘A’.

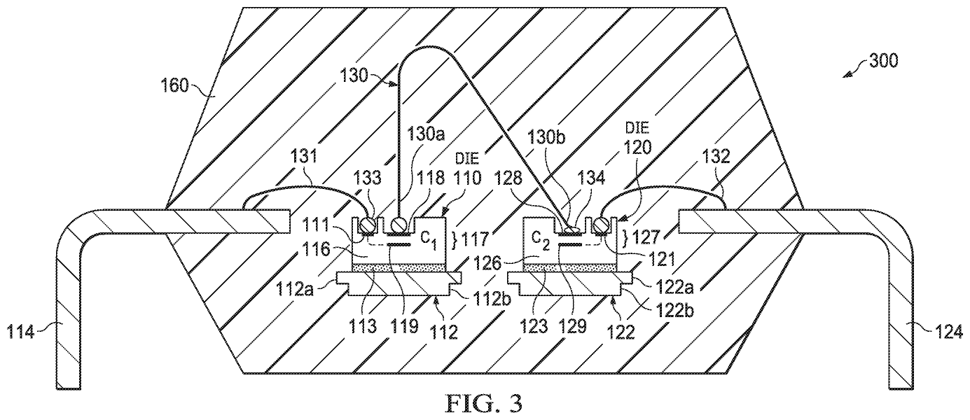

FIG. 1B depicts a side cross section depiction of a packaged MCM device 150 having a disclosed downset first and second die pad 112 and 122 (shown in FIG. 3) of a MCM leadframe having a reduced thickness (thinned) die pad portion within a mold compound 160 shown as only their reduced thickness die pad portions 112a and 122a. Reduced thickness die pad portions can be located outside the vacuum holes areas or outside of the die attach area. The reduced thickness die pad portion 112a and 122a can be seen to have about a half-etch thickness as compared to the metal thickness of the leads 114 and 124.

Although not shown herein, it should be recognized that this Disclosure also applies to leadless leadframes, such as quad flat no lead (QFN) leadframes. The distance from the bottom of the die pads portion 112a and 122a to the bottom edge of the mold compound is shown as Bin FIG. 1B. B can be seen to be greater than A shown in FIG. 1A by an amount shown as C. The die pad portions 112a and 122a in FIG. 1B are moved away by the distance C from the package bottom (A to B, where B>A) by their reduced die pad thickness by the amount C, without changing the downset and the thickness of the mold compound 160. In operation of the MCM device the reduced thickness die pad portions 112a and 122a results in a reduced E-field below the mold compound 160 in the air due to the increased distance to the air, and due to a reduced metal volume a reduced E-field both above and below the mold compound 160.

FIG. 1C is a side cross sectional depiction of a packaged MCM device 170 having a conventional vertically shifted up first and second die pad 182, 192 of a MCM leadframe within a mold compound 160, and FIG. 1D depicts a side cross section depiction of a packaged MCM device 180 having a disclosed vertically shifted up first and second die pad 112b, 122b of a MCM leadframe having a reduced thickness (thinned) die pad portion within a mold compound 160. The distance from the top of the die pads portion 112b and 122b to the top edge of the mold compound 160 is shown as B in FIG. 1D. B can be seen to be greater than A shown in FIG. 1C by the amount shown as C. The tops of the die pad portions 112a and 122a in FIG. 1B are thus moved away by the distance C from the package top by their reduced die pad thickness by the amount C, without changing the vertical down position of the die pads and the thickness of the mold compound 160. In operation of the MCM device the reduced thickness die pad portions 112a and 122a results in a reduced E-field above the mold compound 160 due to the increased distance, and due to a reduced metal volume a reduced E-field both above and below the mold compound 160.

Disclosed leadframes having die pads with reduced thickness portions can be formed using a masked etch process that uses an etch mask to protect the full thickness die pad portions. It is generally desirable to have some full metal thickness portions, such as in the die attach area, and to ensure mechanical strength and flatness for vacuum stabilization during the assembly process. A liquid (chemical spray) or gaseous etchant can be used before the etching process. After etching, the etch mask is then removed. In one particular arrangement the full metal thickness is 254 μm, and the reduced thickness portion is 152 μm. The etching depth can be controlled by the etching time. The etching of the die pad can be performed on the bottom side, on the top side, or on both the bottom side and on the top side.

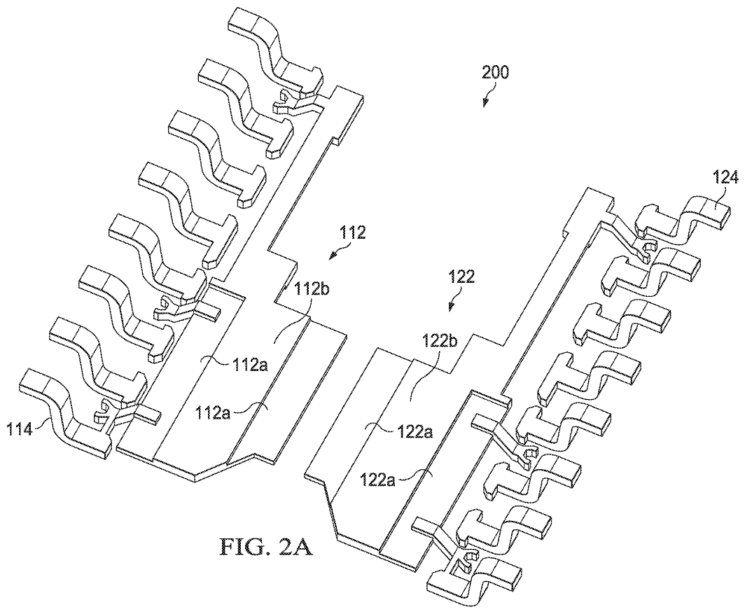

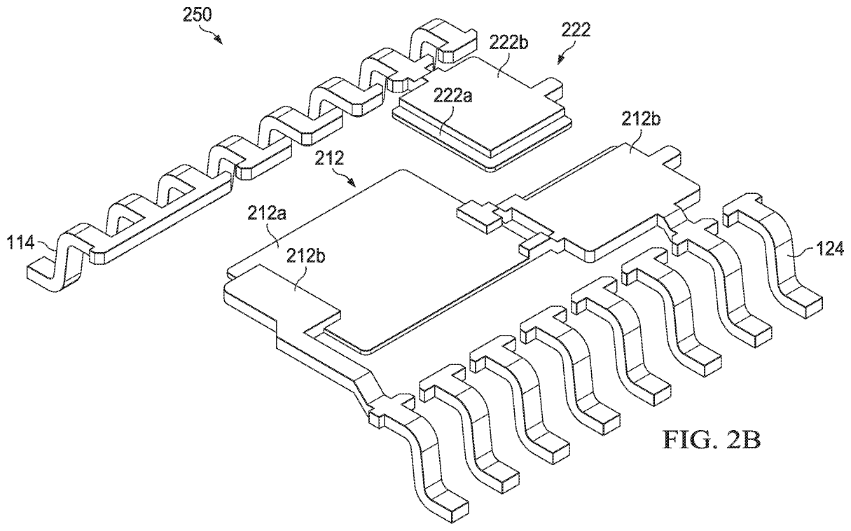

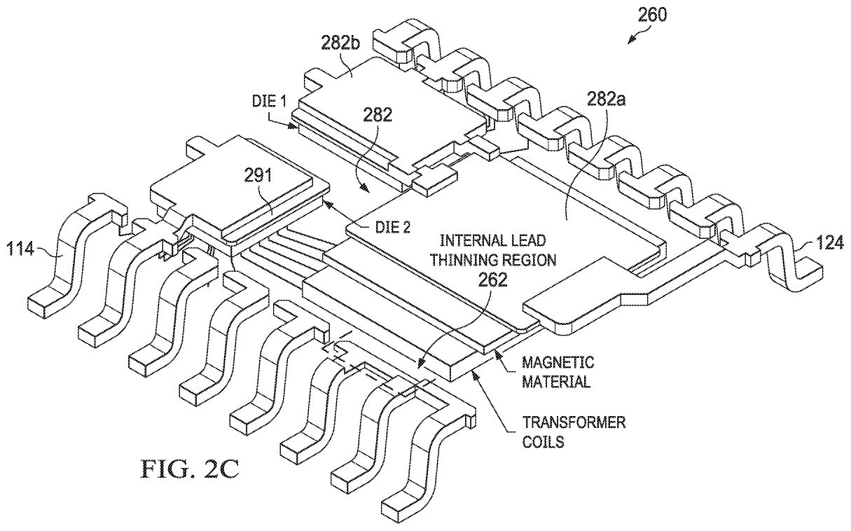

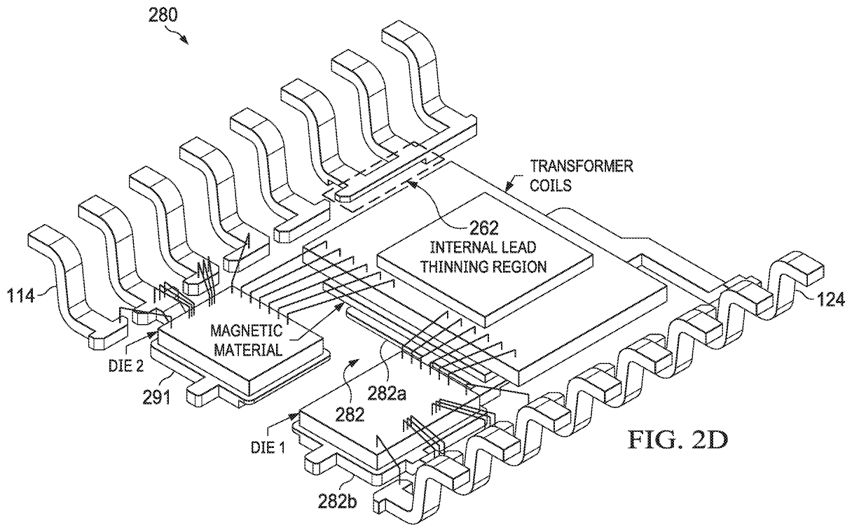

FIG. 2A shows a MCM leadframe 200 having a first die pad 112 and second die pad 122 each having reduced thickness die pad portion 112a, 122a, and a full thickness die pad portion 112b, 122b. Leads are shown as 114 on one side of the leadframe and 124 on the other side of the leadframe. FIG. 2B shows another MCM leadframe 250 having a first die pad 212 and second die pad 222 each having reduced thickness die pad portion 212a, 222a and full thickness die pad portions 212b, 222b. Leads are again shown as 114 and 124.

FIG. 2C shows a MCM leadframe 260 with a vertically shifted die pads 282 and 291, with a thinned inner lead region 262 shown as an “internal lead thinning region” for some of the leads 114 and full thickness inner and outer lead portions for other of the leads 114 and the leads 124, with the outer leads portions of the leads 114 and 124 shown bent down. Inner lead portions as used herein refer to the lead portion within the mold compound 160, and outer lead portions as used herein refer to the lead portions outside the mold compound 160.

Die pad 282 is shown having a reduced thickness die pad portion 282a. Transformer coils with magnetic material are shown on the reduced thickness die pad portion 282a along with a die shown as Die 1 on a full thickness portion 282b of the die pad 282, and Die 2 is shown on die pad 291. Bond wires are also shown.

FIG. 2D shows a MCM leadframe 280 with a vertically shifted die pads 282 and 291, with a thinned inner lead region 262 again shown as an “internal lead thinning region” for some of the leads 114 and full thickness inner and outer lead portions for some of the other leads 114 and the leads 124, with the outer leads portions of the leads 114 and 124 bent up. As with FIG. 1C, the transformer coils with magnetic material are shown on the reduced thickness die pad portion 282a along with Die 1 on the full thickness portion 282b of the die pad 282, and Die 2 is on die pad 291. Bond wires are also shown.

FIG. 3 is a cross sectional view of an example packaged MCM ISO device 300 having reinforced isolation with ISO caps on respective IC die 110 and 120 wire bonded together, according to an example aspect. A first IC die 110 is on a die attach adhesive 113 on a first die pad 112 that includes functional circuitry 116 with a metal stack 117 thereon including a top metal layer and a plurality of lower metal layers. Being a packaged MCM ISO device 300 the functional circuitry 116 (and functional circuitry 126 described below) are configured for realizing a transmitter or a receiver. The first IC die 110 includes at least a first isolation capacitor (first ISO cap) shown as C₁ that utilizes the top metal layer as a first top plate 118 and has a first bottom plate 119.

Due to the series connection provided by the ISO caps, during operation of the packaged MCM ISO device 300 based on the voltage divider rule the bondwire 130 is generally at one half the HV difference between the bottom plate 119 of the first IC die 110 and the bottom plate 129 of the second IC die 120. However, in some somewhat uncommon applications, the voltage on the top plate may not be equal to one half the HV difference, but instead some other fraction that results from the respective ISO cap capacitances not being equal to one another in the series assembly. The full HV appears between the first die pad 112 and the second die pad 122 (same HV as being between the bond pad 111 and the bond pad 121).

The first top plate 118 has a top dielectric layer thereon that has a top plate dielectric aperture, with one of the lower metal layers as its bottom plate. Similarly, a second IC die 120 is on the die attach adhesive 123 on the second die pad 122 including functional circuitry 126 with a metal stack thereon 127 including a top metal layer and a plurality of lower metal layers, with at least a second ISO cap shown as C₂ utilizing the top metal layer as the second top plate 128 along with the second bottom plate 129. The second top plate 128 has a top dielectric layer thereon having a top plate dielectric aperture and one of the lower metal interconnect layers as its bottom plate.

Bond pads comprising the top metal layer are indirectly coupled to the bottom plates 119 and 129 of the ISO caps through vias and intermediate metal levels as well as circuitry. The bond pad 111 is coupled by connection circuitry depicted by a dashed line to the first bottom plate 119, and the bond pad 121 coupled by connection circuitry depicted by a dashed line to the second bottom plate 129. The circuitry for coupling bond pads to the bottom plates 119 and 129 generally comprises analog-to-digital converters or digital-to-analog converters which includes groups of transistors, before going through vias and the respective metal levels of their metal stacks to reach their respective bond pads 111 and 121.

During packaged MCM ISO device 300 operation, there is generally an analog signal that comes into the device externally from the first lead 114 and the second lead 124 that get connected by bondwires 131, 132 to the die bond pads 111 and 121, respectively. In typical operation, there will generally be signals either coming from the first lead 114 pin that gets sent across to the other side of the isolation barrier, such as to the pin of the second lead 124, or coming from second lead 124 and being sent across the isolation barrier back to first lead 114. One series cap HV cap pair either transmits across the ISO barrier or receives from the other side of the ISO barrier, but not both. Generally, there can be more than one communication “channel” on the IC die and the die can have either one channel as a transmit channel and 3 channels as receive channels (on a 4-channel device), or any combination of transmit/receive channels on a device that has 1 to 6 channels. Then the signal from the die bond pads 111 and 121 get routed to signal processing circuitry to send/receive digital signals to the bottom plates 119 and 129 that will transmit across the ISO barrier provided by C₁ and C₂.

The leads 114, 124 together with the first die pad 112 and second die pad 122 may collectively be termed a ‘split leadframe’. The leadframe as known in the art is generally manufactured by plating Ni and Au material onto a flat sheet of copper or copper-alloy material, and either etching or stamping this material into the desired form to provide external pads, routing, and die supports within the package.

Functional circuitry 116 and 126 more generally realizes and carries out a desired functionality, such as that of a digital IC or an analog IC, and in one aspect comprises a BiCMOS (MOS and Bipolar) IC. The capability of the functional circuitry provided on an IC mentioned herein may vary, for example ranging from a simple device to a complex device.

A first end 130a of the bondwire 130 is coupled within the top plate aperture on the first top plate 118. A second end 130b of the bondwire 130 is coupled within the top plate aperture on the second top plate 128. Although each IC die 110, 120 is shown having a single ISO cap so that there is a single ISO cap to ISO cap bondwire, each IC die can have multiple ISO caps so that there can be a plurality of disclosed ISO Cap to ISO Cap bondwires.

The bondwire 130 is embedded in a mold compound 160, typically a heterogeneous material comprising epoxy with embedded silica filler particles. The second end 130b of the bondwire includes a stitch bond shown as 134. There is a ball 133 shown on the first top plate 118, and on the bond pads 111 and 121.

The first ISO and second ISO caps C₁ and C₂ generally can have silicon oxide as their capacitor dielectric layer. The ISO caps and generally have a capacitor dielectric layer thickness of at least 4 μm to provide a nominal breakdown voltage of at least 2,000 Volts. The capacitor dielectric layer thickness is more generally 2 μm to 20 μm.

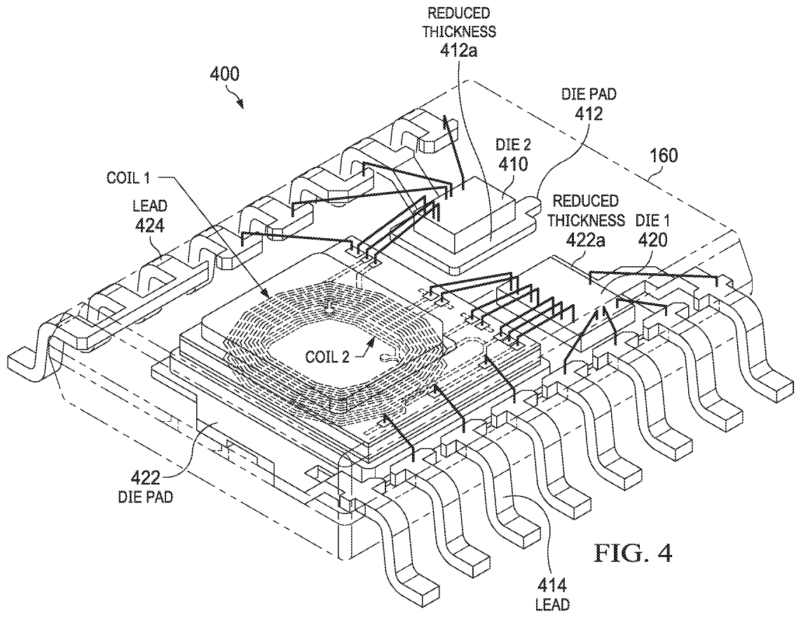

FIG. 4 shows an example packaged MCM ISO device 400 that has disclosed die pads 412 and 422 with reduced thickness die pad portions 412a and 422a. The packaged MCM ISO device 400 has die pad 422 downset relative to external lead form of leads 414, 424, having 16 pins, 8 on each side. The die pad 412 has an IC Die 2 410 thereon showing bond wires, and on the die pad 422 there was also a magnetic enhanced laminate transformer (coil 1 and coil 2 shown) and an IC die 1 420 thereon. There are leads on opposite sides of the packaged ISO device 400 with lead 424 identified on a first side and lead 414 identified on the second side opposite to lead 424. The bond wires are to the IC Die 2 410 that is on die pad 412. The air volume external to the packaged ISO device 400 between the external portion on the lead 424 and the outer edge of the mold compound 160 extending to under the bottom of the mold compound 160 without the reduced thickness die pad portions 412a and 422a can have an E field high enough to cause the air there to ionize, being at least between 2 and 3 Volts/μm. However, the reduced thickness die pad portions 412a and 422a as described can reduce the E field well below 2 Volts/μm to prevent the air from ionizing.

Disclosed aspects can be integrated into a variety of assembly flows to form a variety of different semiconductor IC devices and related products. The assembly can comprise single semiconductor die or multiple semiconductor die, such as PoP configurations comprising a plurality of stacked semiconductor die. A variety of package substrates may be used. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, insulated-gate bipolar transistor (IGBT), CMOS, BiCMOS and MEMS.

### Examples

Disclosed aspects are further illustrated by the following specific Examples, which should not be construed as limiting the scope or content of this Disclosure in any way.

Data was simulated for a packaged MCM ISO device resembling the packaged MCM ISO device 300 in FIG. 3 to generate a plot on the y-axis being the voltage applied from 4 kV and 10 kV between the first and second die pads and on the x-axis the E-field volume (>3V/μm) measured under the mold compound between the die pads in mm³. The die pad to die pad separation distance was 0.609 mm, and the downset distance was 356 μm. The devices with control leadframes had die pads with a full metal thickness throughout of 254 μm, and devices with disclosed die pads had portions of their bottom side etched from a full metal thickness of 254 μm to a reduced thickness portion having a metal thickness of 152 μm. The total mold compound thickness from the top to the bottom of the packages was 2.286 mm.

The control distance from the bottom of the die pads to the bottom of the mold compound was 660 μm, and for the disclosed leadframe this distance due to die pad thinning was increased to 787 μm. The E field in the air at the bottom of the package was thus reduced by the disclosed leadframe having thinned die pad portions to mitigate lead to lead arcing through the air. The disclosed die pad having thinned die portions demonstrated that the E-field was reduced in an applied voltage range of 6.5 kV to 10 kV, where the E field volume vs. the device with the control leadframe was reduced about 0.1 mm³ (>3V/μm) at 6.5 kV bias (from 0.78 to 0.68 in mm³), and was reduced 0.47 mm³ (>3V/μm) under a 9 kV bias (from 8.33 to 7.84 in mm³).

Those skilled in the art to which this Disclosure relates will appreciate that many variations of disclosed aspects are possible within the scope of the claimed invention, and further additions, deletions, substitutions and modifications may be made to the above-described aspects without departing from the scope of this Disclosure.

1. A leadframe for a multichip semiconductor package, comprising:
a first die pad and at least a second die pad both vertically offset at least 0.2 mm relative to leads or lead terminals that are positioned on at least 2 sides beyond the first die pad and the second die pad,
wherein at least one of the first and second die pads has a reduced thickness portion and a full thickness portion, and wherein the full thickness portion has a same thickness as a thickness of at least an outside portion of the leads or the lead terminals.

2. The leadframe of claim 1, wherein the reduced thickness portion has a thickness that is 20% to 80% of the full thickness portion.

3. The leadframe of claim 1, wherein both the first and second die pads have the reduced thickness portion.

4. The leadframe of claim 1, wherein the full thickness portion is between the first and second ones of the reduced thickness portion.

5. The leadframe of claim 1, wherein the reduced thickness portion is on a bottom side of the first die pad and the second die pad.

6. The leadframe of claim 1, further comprising thinning in a portion of an inside portion of the leads or the lead terminals.

7. The leadframe of claim 1, wherein the vertically offset comprises a downset.

8. The leadframe of claim 1, wherein the vertically offset comprises a vertically up offset.

9. A multichip isolation device package, comprising;
a first die pad and at least a second die pad both vertically offset at least 0.2 mm relative to leads or lead terminals that are positioned on at least 2 sides beyond the first die pad and the second die pad, wherein at least one of the first and second die pads has a reduced thickness portion and a full thickness portion, and wherein the full thickness portion has a same thickness as a thickness of at least an outside portion the leads or the lead terminals;
a first integrated circuit (IC) die on the first die pad which has a first bond pad connected to a first of the leads or the lead terminals, the first IC die including functional circuitry configured for realizing a transmitter or a receiver;
a second IC die on the second die pad which has a second bond pad connected to a second of the leads or the lead terminals, the second IC die including functional circuitry configured for realizing another of the transmitter and the receiver, and
an isolation component in a signal path of the isolation device including a capacitive isolator on at least one of the first and second IC die for capacitive isolation, or a first and second inductor for transformer isolation positioned on or between the first and the second IC die.

10. The multichip package of claim 9, wherein the isolation component comprises the capacitive isolator.

11. The multichip package of claim 9, wherein the isolation component comprises the transformer isolation.

12. The multichip package of claim 9, wherein the reduced thickness portion has a thickness that is 20% to 80% of the full thickness portion.

13. The multichip package of claim 9, wherein both the first and second die pads have the reduced thickness portion.

14. The multichip package of claim 13, wherein the full thickness portion is under the first IC and the second IC die and is positioned between the first and second ones of the reduced thickness portion.

15. The multichip package of claim 9, further comprising thinning in a portion of an inside portion of the leads or the lead terminals.

16. The multichip package of claim 9, wherein the vertically offset comprises a downset.

17. A method of fabricating a multichip semiconductor isolation device package, comprising:
providing at least one leadframe including a first die pad and at least a second die pad both vertically offset at least 0.2 mm relative to leads or lead terminals that are positioned on at least 2 sides beyond the first die pad and the second die pad, and
masked etching on at least one side of the first die pad and the second die pad to provide a reduced thickness portion and a full thickness portion that has a same thickness as a thickness as an outer portion of the leads or the lead terminals;
mounting a first integrated circuit (IC) die on the first die pad which has a first bond pad connected to a first of the leads or the lead terminals, the first IC die including functional circuitry configured for realizing a transmitter or a receiver and a second IC die on the second die pad which has a second bond pad connected to a second of the leads or the lead terminals, the second IC die including functional circuitry configured for realizing another of the transmitter and the receiver,
wherein there is an isolation component in a signal path of the isolation device including a capacitive isolator on at least one of the first and second IC die for capacitive isolation, or a first and second inductor for transformer isolation positioned on or between the first and the second IC die;
molding with a mold compound to form a molded body encapsulating the first and second IC die and the first and second die pads, where the outer portion leads extend outside the molded body,
wherein the leadframe is part of a leadframe strip with a plurality of the leadframes.

18. The method of claim 17, wherein the reduced thickness portion has a thickness that is 20% to 80% of the full thickness portion.

19. The method of claim 17, wherein both the first and second die pads have the reduced thickness portion.

20. The method of claim 17, wherein masked etching further comprises thinning a portion of an inside portion of the leads or the lead terminals.
